(19) United States
(12) Patent Application Publication
(10) Pub. No.: US 2021/0018275 A1
(43) Pub. Date: Jan. 21, 2021

(54) LAYER-BY-LAYER PHASE CHANGE COMPOSITE HAVING IMPROVED COOLING PERFORMANCE AND HEAT SPREADER INCLUDING THE SAME

(71) Applicant: Industry-University Cooperation Foundation Hanyang University, Seoul (KR)

(72) Inventors: Dong Rip KIM, Seoul (KR); Chang Sung HEU, Seoul (KR); Su Ho KIM, Yongin-si (KR); Heung Soo LEE, Seoul (KR); Hyeon Woo SON, Busan (KR)

(73) Assignee: Industry-University Cooperation Foundation Hanyang University, Seoul (KR)

(21) Appl. No.: 16/931,687

(22) Filed: Jul. 17, 2020

(30) Foreign Application Priority Data
Jul. 19, 2019 (KR) 10-2019-0087854
Sep. 23, 2019 (KR) 10-2019-0116975

(51) Int. Cl. F28D 20/02; H05K 7/20; C09K 5/14; C09K 5/06

(52) U.S. Cl. CPC F28D 20/021; C09K 5/063; C09K 5/14; H05K 7/20336

(57) ABSTRACT

The present disclosure relates to a phase change composite and a heat spreader including the same, and more particularly, to a phase change composite having improved cooling performance by being formed in a layer-by-layer structure composed of a material having high thermal conductivity and a phase change material. According to the present disclosure, by repeatedly laminating thermal conductive layers and phase change material unit layers, thermal conductivity in the horizontal direction may be dramatically improved. In addition, due to a high volume percentage of a phase change material, a heat spreader with a large heat capacity may be provided.

### CROSS-REFERENCE TO RELATED APPLICATIONS

This application claims priority to Korean Patent Application No. 10-2019-0087854, filed on Jul. 19, 2019, and Korean Patent Application No. 10-2019-0116975, filed on Sep. 23, 2019, in the Korean Intellectual Property Office, the disclosures of each of which are incorporated herein by reference.

### BACKGROUND OF THE DISCLOSURE

### Field of the Disclosure

The present disclosure relates to a phase change composite and a heat spreader including the same, and more particularly, to a phase change composite having improved cooling performance by being formed in a layer-by-layer structure composed of a material having high thermal conductivity and a phase change material and a heat spreader including the phase change composite.

### Description of the Related Art

Recently, with the trend toward miniaturization of electronic equipment or battery equipment and integration of components for performance improvement, thermal management of electronic equipment has emerged as a very important issue. When heat generated inside electronic equipment is not properly discharged or cooled, the performance of the equipment may deteriorate and the lifespan of the equipment may be shortened. Accordingly, various studies on thermal management have been conducted to prevent degradation of equipment performance and prolong equipment lifespan. In particular, research into cooling using phase change materials has been actively conducted.

Examples of typical phase change materials include paraffin and erythritol, which are organic phase change materials. These organic phase change materials have a relatively large amount of latent heat, but due to low thermal conductivity thereof, the organic phase change materials have the disadvantage that heat transfer is not smooth. In addition, due to low thermal conductivity of the phase change materials, smooth transfer of heat in the phase change materials is suppressed in exothermic conditions, which leads to accumulation of heat in a heat generating portion and consequently, causes overheating. Therefore, to date, phase change materials have difficulty functioning as a heat spreader due to low thermal conductivity.

Conventionally, only a material having excellent thermal conductivity has been used as a heat spreader. Representative examples of the materials having excellent thermal conductivity include graphite sheets, metal plates, heat pipes, and the like. The purpose of use of such materials is to improve the diffusivity of heat in a heat generating portion due to high thermal conductivity. However, such a heat spreader has limited cooling performance. Thus, in a condition wherein strong heat is temporarily generated or cooling is not smoothly performed, the heat spreader cannot control overheating of a heat generating portion.

In relation to a heat spreader, Korean Patent Application Publication No. 10-2003-0042652 discloses a method of manufacturing a heat spreader that is brought into contact with and installed on the surface of an electronic device to discharge heat generated from the electronic device to the outside. The heat spreader manufactured using the above method has excellent heat diffusion performance through heat conduction, but has the disadvantage that heat absorption performance is degraded due to low specific heat. Korean Patent No. 10-1956370 discloses a method of manufacturing, using aluminum oxide, a material having excellent insulation properties and capable of effectively dissipating heat generated from electrical and electronic products without adjusting the thickness of a heat dissipation sheet or forming a complicated structure. However, due to the low thermal conductivity of an insulating material, in terms of cooling performance, the material of Korean Patent No. 10-1956370 is inferior to conventional heat spreaders. Korean Patent No. 10-1810167 discloses a three-dimensional heat absorbing device for absorbing heat transferred from an external heat source to suppress temperature rise of the heat source. According to Patent No. 10-1810167, by filling the device with a phase change material, heat storage performance may be imparted to the device. However, since the device is not manufactured in a multilayer laminating manner, the filling rate of the phase change material is limited.

### SUMMARY OF THE DISCLOSURE

Therefore, the present disclosure has been made in view of the above problems, and it is an object of the present disclosure to provide a high-performance layer-by-layer phase change composite having a layer-by-layer structure composed of a highly thermally conductive material having high-density heat capacity and excellent thermal conductivity and a phase change material and a heat spreader including the high-performance layer-by-layer phase change composite.

In accordance with one aspect of the present disclosure, provided is a phase change composite including a structure wherein phase change material unit layers and thermal conductive layers are sequentially laminated.

Each of the phase change material unit layers may include a metal mesh sheet in which a plurality of unit cells is formed; and a phase change material, wherein the unit cells are impregnated with the phase change material.

Each of the unit cells may have a rectangular shape characterized in that a length thereof is longer than a width thereof based on a horizontal direction.

The phase change material may be a salt hydrate, a molten salt, a fatty acid, a liquid metal (gallium, indium), a phase change material made up of molecular alloys (MCPAM), an organic phase change material, an inorganic phase change material, or a eutectic phase change material, and the phase change material may be polyethylene glycol (PEG), paraffin, or erythritol.

The metal mesh sheet may be formed of one or more selected from the group consisting of aluminum, copper, nickel, brass, iron, cadmium, gold, platinum, tungsten, zinc, zirconium, carbon steel, stainless steel, and galvanized steel.

Thermal properties of the phase change composite may change depending on changes in a volume percentage (vol %) of the metal mesh sheet and a volume percentage (vol %) of the phase change material, and the thermal properties may include thermal conductivity and amount of heat absorption.

The thermal conductive layers may be formed of one or more selected from the group consisting of graphite, graphene, carbon nanotube, fullerene, aluminum oxide, copper oxide, silver oxide, gold oxide, palladium oxide, platinum oxide, nickel oxide, and yttrium oxide.

In accordance with another aspect of the present disclosure, provided is a heat spreader including the phase change composite.

In accordance with yet another aspect of the present disclosure, provided is a method of manufacturing a phase change composite, the method including preparing a metal mesh sheet in which a plurality of unit cells is formed; manufacturing phase change material unit layers by impregnating the unit cells with a phase change material; manufacturing a laminated structure by sequentially and alternately laminating the phase change material unit layers and thermal conductive layers so that each of the thermal conductive layers is laminated on an upper portion of each of the phase change material unit layers; and manufacturing the phase change composite by compressing the laminated structure.

The phase change material may be a salt hydrate, a molten salt, a fatty acid, a liquid metal (gallium, indium), a phase change material made up of molecular alloys (MCPAM), an organic phase change material, an inorganic phase change material, or a eutectic phase change material, and the phase change material may be polyethylene glycol (PEG), paraffin, or erythritol.

The metal mesh sheet may be formed of one or more selected from the group consisting of aluminum, copper, nickel, brass, iron, cadmium, gold, platinum, tungsten, zinc, zirconium, carbon steel, stainless steel, and galvanized steel.

The thermal conductive layers may be formed of one or more selected from the group consisting of graphite, graphene, carbon nanotube, fullerene, aluminum oxide, copper oxide, silver oxide, gold oxide, palladium oxide, platinum oxide, nickel oxide, and yttrium oxide.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic diagram of a phase change composite of the present disclosure;

FIG. 2 is a schematic diagram of a unit layer included in a phase change composite of the present disclosure;

FIG. 3 is a flowchart showing a process of manufacturing a phase change composite according to an embodiment of the present disclosure;

FIG. 4 is an image of a phase change composite according to an embodiment of the present disclosure;

FIG. 5 is a cross-sectional SEM image of a phase change composite according to an embodiment of the present disclosure;

FIG. 6 is a schematic diagram of an experimental device for measuring the thermal diffusion performance of a phase change composite according to an embodiment of the present disclosure;

FIG. 7A illustrates a numerical analysis model for a phase change composite according to an embodiment of the present disclosure;

FIG. 7B illustrates a numerical analysis model for a phase change composite according to an embodiment of the present disclosure;

FIG. 8A shows the thermal conductivity of pure paraffin (marked as Paraffin) as a heat spreader and the thermal conductivity of a phase change composite (marked as Phase Change Composite) according to an embodiment of the present disclosure as a heat spreader in the horizontal direction (x-y direction) and the vertical direction (z direction) thereof;

FIG. 8B shows numerical simulation values for the thermal conductivity of pure paraffin (marked as Paraffin) as a heat spreader and the thermal conductivity of a phase change composite (marked as Phase Change Composite) according to an embodiment of the present disclosure as a heat spreader in the x-axis and the y-axis thereof;

FIG. 9 shows the results of differential scanning calorimetry (DSC) (DSC 4000, PERKIN ELMER) analysis of pure paraffin (marked as Paraffin) and a phase change composite (marked as Phase Change Composite) according to an embodiment of the present disclosure;

FIG. 10 shows temperatures and numerical simulation values measured at one point in a thermal diffusion measurement device according to an embodiment of the present disclosure;

FIG. 11A shows the results of measuring, for 60 minutes, the temperature of the heat generating portion of each of pure paraffin (marked as Paraffin), an aluminum block (marked as Aluminum), and a phase change composite (marked as Phase Change Composite) according to an embodiment of the present disclosure, which have the same volume under natural convection conditions (a simplified schematic diagram of an experimental apparatus for verifying cooling performance is shown at the upper left of FIG. 11A);

FIG. 11B shows the results of measuring, for 60 minutes, the temperature of the heat generating portion of each of pure paraffin (marked as Paraffin), an aluminum block (marked as Aluminum), and a phase change composite (marked as Phase Change Composite) according to an embodiment of the present disclosure, which have the same volume under conduction cooling conditions (a simplified schematic diagram of an experimental apparatus for verifying cooling performance is shown at the upper left of FIG. 11B);

FIG. 12A shows the maximum temperatures (hot-spot temperatures) of pure paraffin (marked as Paraffin), an aluminum block (marked as Aluminum), and a phase change composite (marked as Phase Change Composite) according to an embodiment of the present disclosure under low (insulator), medium (natural convection), and high (conduction cooling) conditions;

FIG. 12B shows the normalized temperatures of pure paraffin (marked as Paraffin), an aluminum block (marked as Aluminum), and a phase change composite (marked as Phase Change Composite) according to an embodiment of the present disclosure under low (insulator), medium (natural convection), and high (conduction cooling) conditions. Here, the normalized temperature is obtained by dividing the difference between maximum temperature and ambient temperature by the ambient temperature, and differences in heating and cooling fluxes are shown in the low, medium, and high conditions;

FIG. 13 shows images, taken with a thermal imaging camera, showing the temperatures of pure paraffin (marked as Paraffin), an aluminum block (marked as Aluminum), and a phase change composite (marked as Phase Change Composite) according to an embodiment of the present disclosure under exothermic conditions for 60 minutes;

FIG. 14 shows the coefficients of thermal spreading (CTS) of pure paraffin (marked as Paraffin), an aluminum block (marked as Aluminum), and a phase change composite (marked as Phase Change Composite) according to an embodiment of the present disclosure for the same time; and

FIGS. 15A and 15B show the cooling performance of thermal identification under natural convection conditions according to heating power for pure paraffin (marked as Paraffin), an aluminum block (marked as Aluminum), and a phase change composite (marked as Phase Change Composite) according to an embodiment of the present disclosure, wherein FIG. 15A relates to maximum temperature (hot-spot temperature) and FIG. 15B relates to normalized temperature.

### DETAILED DESCRIPTION OF THE DISCLOSURE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context. It will be further understood that the terms “comprise” and/or “comprising”, when used in this specification, specify the presence of stated components, steps, operations, and/or elements, but do not preclude the presence or addition of one or more other components, steps, operations, and/or elements thereof.

It should not be understood that arbitrary aspects or designs disclosed in “embodiments”, “examples”, “aspects”, etc. used in the specification are more satisfactory or advantageous than other aspects or designs.

Although terms used in the specification are selected from terms generally used in related technical fields, other terms may be used according to technical development and/or due to change, practices, priorities of technicians, etc. Therefore, it should not be understood that terms used below limit the technical spirit of the present disclosure, and it should be understood that the terms are exemplified to describe embodiments of the present disclosure.

Also, some of the terms used herein may be arbitrarily chosen by the present applicant. In this case, these terms are defined in detail below. Accordingly, the specific terms used herein should be understood based on the unique meanings thereof and the whole context of the present disclosure.

Meanwhile, terms such as “first” and “second” are used herein merely to describe a variety of constituent elements, but the constituent elements are not limited by the terms. The terms are used only for the purpose of distinguishing one constituent element from another constituent element.

In addition, when an element such as a layer, a film, a region, and a constituent is referred to as being “on” another element, the element can be directly on another element or an intervening element can be present.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein

In addition, in the following description of the present disclosure, a detailed description of known functions and configurations incorporated herein will be omitted when it may make the subject matter of the present disclosure unclear. The terms used in the specification are defined in consideration of functions used in the present disclosure, and can be changed according to the intent or conventionally used methods of clients, operators, and users. Accordingly, definitions of the terms should be understood on the basis of the entire description of the present specification.

Hereinafter, embodiments of the present disclosure will be described in detail with reference to the accompanying drawings.

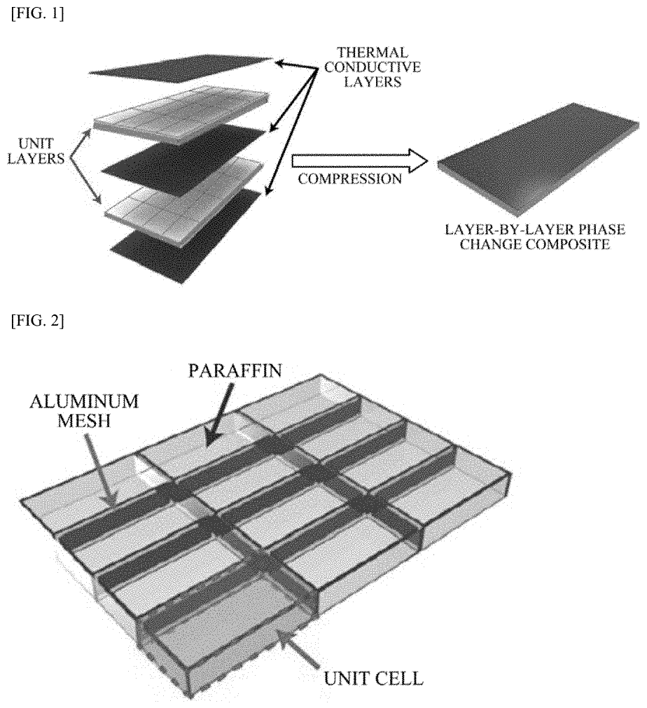

Referring to FIG. 1, a phase change composite of the present disclosure includes a structure wherein phase change material unit layers and thermal conductive layers are sequentially laminated.

Each of the phase change material unit layers may include a metal mesh sheet in which a plurality of unit cells is formed and a phase change material, wherein the unit cells are impregnated with the phase change material.

The phase change material may be a material, the phase of which changes at a temperature lower than the melting point of the metal mesh sheet. For example, the phase change material may be a salt hydrate, a molten salt, a fatty acid, a liquid metal (gallium, indium), a phase change material made up of molecular alloys (MCPAM), an organic phase change material, an inorganic phase change material, or a eutectic phase change material. Specifically, the phase change material may be polyethylene glycol (PEG), paraffin, or erythritol, preferably, paraffin or erythritol, more preferably paraffin.

The metal mesh sheet may be formed of one or more selected from the group consisting of aluminum, copper, nickel, brass, iron, cadmium, gold, platinum, tungsten, zinc, zirconium, carbon steel, stainless steel, and galvanized steel, preferably aluminum.

Referring to FIG. 2, in the phase change material unit layer, the metal mesh sheet is an aluminum mesh sheet, and paraffin is used as the phase change material.

The thermal properties of the phase change composite may change depending on changes in the volume percentage (vol %) of the metal mesh sheet and the volume percentage (vol %) of the phase change material. Here, the thermal properties may include thermal conductivity and amount of heat absorption.

The thermal conductive layer may be a sheet composed of one or more selected from the group consisting of graphite, graphene, carbon nanotube, fullerene, aluminum oxide, copper oxide, silver oxide, gold oxide, palladium oxide, platinum oxide, nickel oxide, and yttrium oxide. More preferably, the thermal conductive layer may be a graphite sheet. In this case, the thermal conductivity of the phase change composite may be improved in the horizontal direction (x-y direction), and a sealing effect may also be provided to prevent leakage of the phase change material impregnated in the unit cells.

The unit cell may have a circular, triangular, square, or rectangular shape. More preferably, the unit cell may have a rectangular shape characterized in that the length thereof is longer than the width thereof based on the horizontal direction. In this case, the aspect ratio (A.R) is preferably 8 or less, more preferably, 0.1 to 8. When the aspect ratio (A.R) exceeds 8, change in thermal conductivity according to change in aspect ratio may be less than 2%. This is because thermal resistance in the direction horizontal to the heat transfer direction increases as thermal resistance in the direction perpendicular to the heat transfer direction decreases at the same volume percentage.

In addition, a heat spreader of the present disclosure includes the phase change composite.

In addition, a method of manufacturing a phase change composite of the present disclosure includes a step of preparing a metal mesh sheet in which a plurality of unit cells is formed; a step of manufacturing phase change material unit layers by impregnating the unit cells with a phase change material; a step of manufacturing a laminated structure by sequentially and alternately laminating the phase change material unit layers and thermal conductive layers so that each of the thermal conductive layers is laminated on an upper portion of each of the phase change material unit layers; and a step of manufacturing the phase change composite by compressing the laminated structure.

The phase change material may be a material, the phase of which changes at a temperature lower than the melting point of the metal mesh sheet. For example, the phase change material may be a salt hydrate, a molten salt, a fatty acid, a liquid metal (gallium, indium), a phase change material made up of molecular alloys (MCPAM), an organic phase change material, an inorganic phase change material, or a eutectic phase change material. Specifically, the phase change material may be polyethylene glycol (PEG), paraffin, or erythritol, preferably, paraffin or erythritol, more preferably paraffin.

The metal mesh sheet may be formed of one or more selected from the group consisting of aluminum, copper, nickel, brass, iron, cadmium, gold, platinum, tungsten, zinc, zirconium, carbon steel, stainless steel, and galvanized steel, preferably aluminum.

The thermal conductive layer may be a sheet composed of one or more selected from the group consisting of graphite, graphene, carbon nanotube, fullerene, aluminum oxide, copper oxide, silver oxide, gold oxide, palladium oxide, platinum oxide, nickel oxide, and yttrium oxide. More preferably, the thermal conductive layer may be a graphite sheet. In this case, the thermal conductivity of the phase change composite may be improved in the horizontal direction (x-y direction), and a sealing effect may also be provided to prevent leakage of the phase change material impregnated in the unit cells.

Hereinafter, the present disclosure will be described in more detail through examples. These examples are intended to illustrate the present disclosure more specifically, but the scope of the present disclosure is not limited by these examples.

### Manufacture Example 1. Manufacture of Phase Change Material Unit Layers

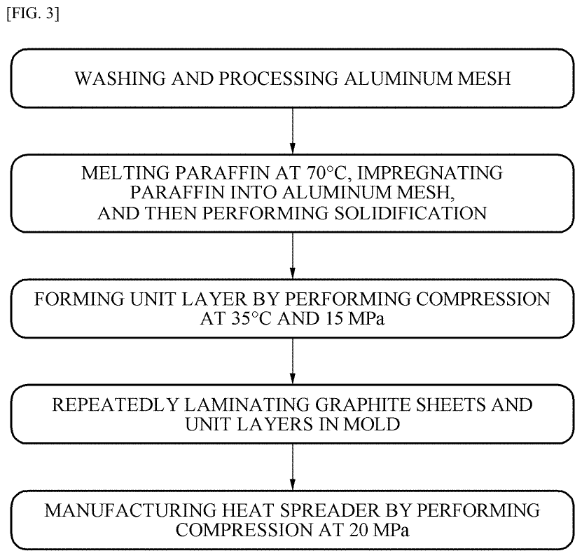

Referring to FIG. 3, an aluminum mesh (Al 1350) having unit cells (width: 3.2 mm, length: 1.6 mm, height: 700 pin) is washed with 0.5 M NaOH for 5 minutes, and etching is performed at 80° C. for 10 minutes using 1 M HCl, followed by washing with distilled water to remove residues. By performing etching, the volume ratio of aluminum to paraffin in a composition is adjusted up to −10%, and the bonding force between a phase change material and aluminum is increased. Thereafter, melting of paraffin wax (n-Tricosane, C₂₃H₄₈, melting point: 48 to 50° C.) is performed at 70° C., the liquid paraffin is injected into the aluminum mesh, and then the molten paraffin is allowed to solidify at room temperature. Then, planarization of the aluminum mesh containing the solidified paraffin is performed at 35° C. and under a pressure of 15 MPa through a hot-pressing process to form a phase change material unit layer having a width of 5 cm, a length of 10 cm, and a height of 700 μm.

### Manufacture Example 2. Manufacture of Phase Change Composite_Manufacture of Heat Spreader

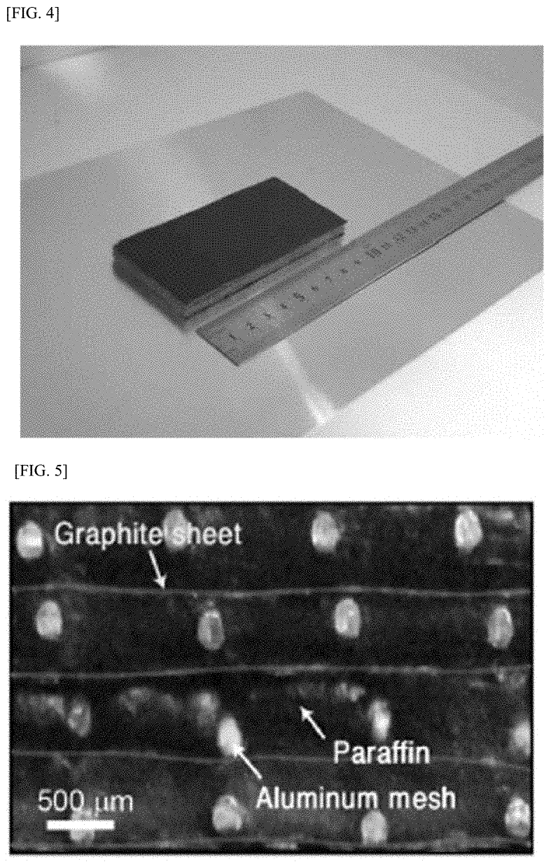

Referring to FIG. 3, a plurality of phase change material unit layers manufactured in Manufacture Example 1 and graphite sheets (thickness: ˜40 μm, thermal conductivity (x-y axis): 1,200 W/m·K, thermal conductivity (z-axis): ˜8 W/m·K, GPC-0025S10B010, SGP) of the same size formed using a mold are alternately laminated. A structure composed of a total of 14 layers including the phase change material unit layers and the graphite sheets is compressed at a pressure of 20 MPa to manufacture a layer-by-layer phase change composite (heat spreader) (width: 5 cm, length: 10 cm, height: ˜1 cm) as shown in FIG. 4.

The phase change composite manufactured in Manufacture Example 2 contains 90 vol % of paraffin wax and 10 vol % of the thermal conductive filler (aluminum mesh+graphite sheet). When the weight and volume of each component of the phase change composite manufactured in Manufacture Example 2 are measured, paraffin wax is contained in an amount of −75 wt % based on the total composition. When conversion is performed using the density of each component (aluminum mesh: 2,700 kg/m³, graphite sheet: 1,200 kg/m³, paraffin wax: 880 kg/m³), the volume percentage of paraffin wax is −90 vol %.

### Measurement Example. Morphology

The morphology of the phase change composite manufactured in Manufacture Example 2 was observed using an optical microscope (BX51M, OLYMPUS), and the obtained morphology image is shown in FIG. 5.

Referring to FIG. 5, it can be seen that, in the phase change composite manufactured in Manufacture Example 2, the graphite sheets and aluminum meshes are repeatedly laminated and paraffin is located on the aluminum meshes.

### Measurement Example. Measurement of Thermal Diffusion Performance

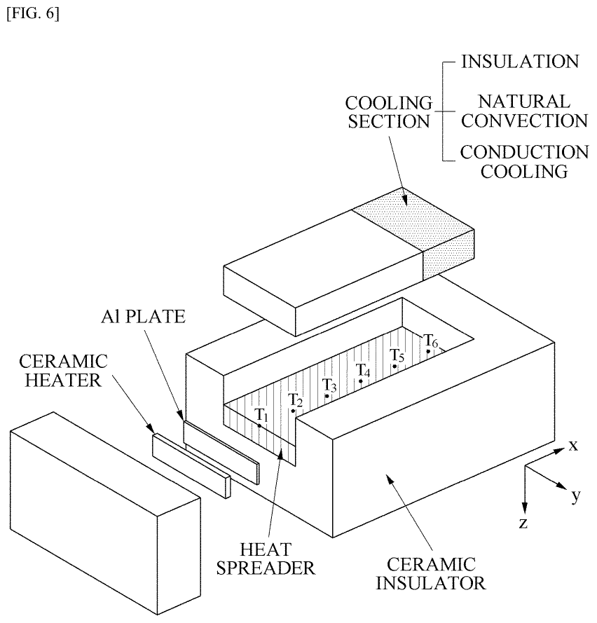

Referring to FIG. 6, to measure thermal diffusion, a one-dimensional heat conduction experimental setup was prepared, and an experiment apparatus including an insulator (calcium silicate, thermal conductivity: 0.058 W/m·K) and a 7 cm×1.5 cm ceramic heater installed in the insulator and controlled by voltages and current was prepared. The heating power of the ceramic heater was expressed as electric power measured by a power meter (117/TLK-225, FLUKE). For constant heat transfer from a heater to a sample material, a thin aluminum plate (Al plate) of 1 mm thickness was inserted between the ceramic heater and the sample material (Heat Spreader). To reduce contact resistance, thermal grease was applied onto the contact surfaces of the ceramic heater, the aluminum plate, and the phase change composite. The sample material (Heat Spreader) to be measured was the phase change composite manufactured in Manufacture Example 2 (width: 5 cm, length: 10 cm, height: ˜1 cm).

Cooling on the opposite side of the phase change composite to be measured is controlled by three cooling conditions, and the three cooling conditions are as follows: (i) an insulating condition wherein an insulating material is applied onto a cooling zone; (ii) a natural convection condition wherein a cooling zone opens at an ambient temperature of 20° C.; (iii) a conduction cooling condition wherein a thermoelectric cooling element is installed in a cooling zone. As shown in FIG. 6, temperatures (T₁ to T₆) at six different points were measured using a type T thermocouple. When thermal diffusion performance was measured, five samples were prepared for each condition, and measurement was repeated three times. The uncertainty (error) of the measured values was ±0.17° C. for temperature, ±2.0% for the electric power of a ceramic heater, and ±2.0% for thermal conductivity.

### Measurement Example. Numerical Simulation

1. Numerical Analysis of Effective Thermal Conductivity of Phase Change Composite (Heat Spreader)

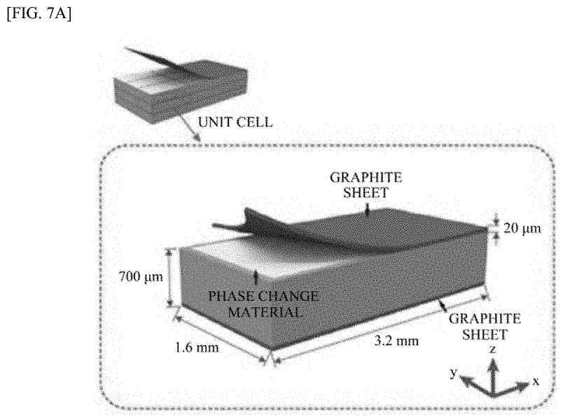

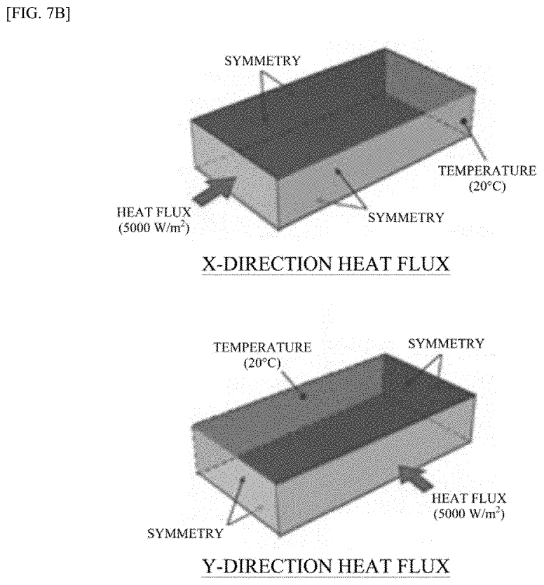

To numerically confirm change in the thermal conductivity of the phase change composite of the present disclosure depending on heat flow directions, numerical analysis was performed using a COMSOL Multiphysics software (Stockholm, Sweden) that solves a normal three-dimensional general heat conduction equation (see FIG. 7A and FIG. 7B). Referring to FIG. 7A, a calculation domain was established on a unit cell, i.e., a simplified phase change composite, that was coated with graphite sheet and was composed of one unit of an aluminum mesh in which a phase change material was impregnated.

FIG. 7B shows boundary conditions depending on the type of heat flux for the x- and y-directions, and the properties of materials are shown in Table 1 below.

Effective thermal conductivity (k_{eff}) is calculated by Equation 1 below according to the Fourier thermal equation.

$${k}_{eff} = \ddot{q} \frac{L}{( {T}_{1} - {T}_{2} )} \qquad [ Equation 1 ]$$

In Equation 1, \ddot{q} represents a heat flux (W/m²), L represents the length (m) of a unit cell depending on heat flow directions, T₁ represents an average temperature (° C.) at the surface of a heat plus boundary, and T₂ represents a constant temperature of 20° C. in FIG. 3B.

In this simulation, 2D quadrilateral lattices are applied to the mesh, and the size thereof affects the results.

According to the results, when analyzing the relative error of the thermal conductivity analysis results of the phase change composite while increasing the number of lattices (the number of meshes), it was confirmed that the analyzed effective thermal conductivity converged within an error range of 0.0002% when the total number of lattices was 43,554.

2. Numerical Analysis of Temperature Profiles of Heat Spreader Over Time

To verify the experimental measurement of a heat spreader, the cooling performance of a heat spreader including pure paraffin, aluminum, and a phase change composite was numerically analyzed. A rectangular simulation domain having a width of 10 cm, a length of 15.1 cm, and a height of 6 cm includes an insulator.

For numerical simulation, conventional transient governing equations, such as a continuity equation, the Navier-Stokes equation, and an energy equation, were used.

In the experiment apparatus of FIG. 6, the boundary conditions of one surface (heater part) are set to have a constant heating rate of 5 W, and the other surface is set to have natural convection conditions (convective heat transfer coefficient: 5 W/m²·K) from the ceramic insulator to the atmosphere. The detailed physical properties of pure paraffin, aluminum, and the phase change composite are summarized in Table 1 below. Numerical simulation was performed using Fluent v14.0, and a mesh using structured lattices was generated. Mesh dependency test according to the results was performed by confirming that monitoring temperature converged to an error rate of 3.7%, the number of lattices was 830,000, and time interval was 0.5 seconds.

Modeling of the phase change process of pure paraffin and the composite was performed using a heat capacity method. In particular, when considering latent heat (i.e., enthalpy of fusion) as shown in Equation 2 below, the specific heat of a phase change material was changed in a melting process (48 to 51° C.).

$${C}_{p , m} = \frac{L}{Δ {T}_{m}} + {C}_{p , l} \qquad [ Equation 2 ]$$

In Equation 2, Cₚ represents specific heat (J/g·K), L represents latent heat (J/g), ΔTm represents a temperature range (° C.) in a melting process, subscript m represents melting, and subscript l represents liquid.

TABLE 1
Thermal properties according to numerical analysis for each material

| | | | Thermal | | | |
|---|---|---|---|---|---|---|
| | Density | Specific heat | conductivity | Latent heat | Melting point | Freezing |
| | (kg/m3) | (J/g · K) | (W/m · K) | (J/g) | (° C.) | Point |
| Paraffin | 880 | 2.13 | 0.21 | 189.6 | 48 to 51 | 48 to 51 |
| Phase | 1,071 | 1.68 | x-y axis: 57 | 135.7 | 48 to 51 | 48 to 51 |
| Change Composite | | | z-axis: 2.4 | | | |
| Aluminum | 2,700 | 0.90 | 230 | — | — | — |

### Measurement Example. Thermal Conductivity

Thermal conductivity was measured using a one dimensional steady-state method (ASTM D5470), steady-state temperature distribution between the upper and lower parts of a sample was measured using a type T thermocouple, and the thermal conductivity of the sample was calculated using a Fourier heat conduction equation. To measure thermal conductivity, copper (thermal conductivity: 401 W/m·K) was used as reference material. The sample was manufactured to have a diameter of 2.5 cm and a height of 1.3 cm.

As the samples, the thermal conductivity of pure paraffin and the thermal conductivity of the phase change composite manufactured in Manufacture Example 2 in the horizontal direction (x-y direction) and the vertical direction (z direction) was measured, and the results are shown in FIG. 6.

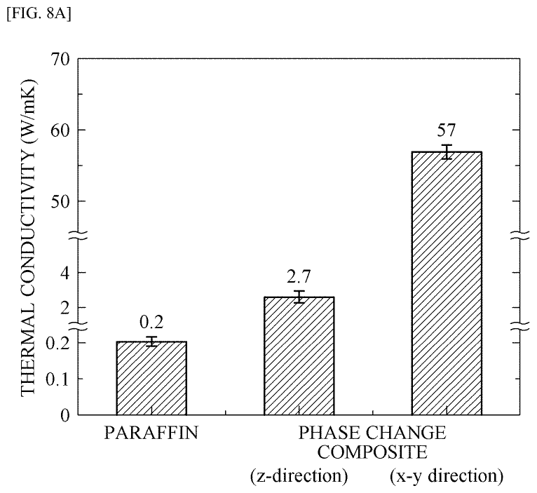

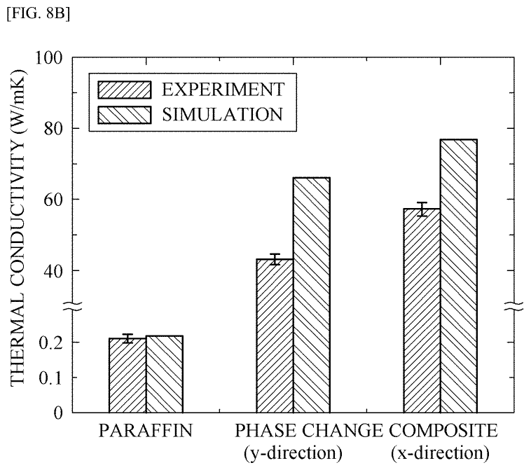

Referring to FIG. 8A, the thermal conductivity of pure paraffin is 0.2±0.1 W/m·K, and the thermal conductivity of the phase change composite manufactured in Manufacture Example 2 (Phase Change Composite Heat spreader) in the horizontal direction (x-y direction) and the vertical direction (z direction) was 57±2.7 W/m·K and 2.4±0.3 W/m·K, respectively. Based on the results, it can be seen that the thermal conductivity of the composite in the horizontal direction is increased by about 258 times compared to pure paraffin. This dramatic improvement in thermal conductivity suggests that low thermal conductivity, which is a limitation of conventional phase change materials, may be overcome, and that the heat diffusion function of a heat generating portion may be significantly improved when the composite is used as a heat spreader.

In addition, referring to FIG. 8B, the thermal conductivity of the phase change composite manufactured in Manufacture Example 2 in the x-axis and y-axis directions is shown, and the thermal conductivity in the x-axis direction is 57±2.7 W/m·K and the thermal conductivity in the y-axis direction is 43±1.4 W/m·K. The thermal conductivity in the x-axis direction is about 1.3 times higher than that in the y-axis. This result is due to the length being longer than the width in the unit cell. In contrast to a case wherein a heat flux is applied to the y-axis, when a heat flux is applied to the x-axis, the thermal resistance of the internal phase change material (paraffin) in the direction perpendicular to a heat transfer direction is small, which affects the large thermal resistance of the internal phase change material in the direction parallel to the heat transfer direction. In addition, referring to FIG. 8B, it can be confirmed that the measured values (Experiment) correspond to the results (Simulation) according to the numerical simulation described above.

### Measurement Example. Amount of Latent Heat, Heat of Fusion, and Specific Heat

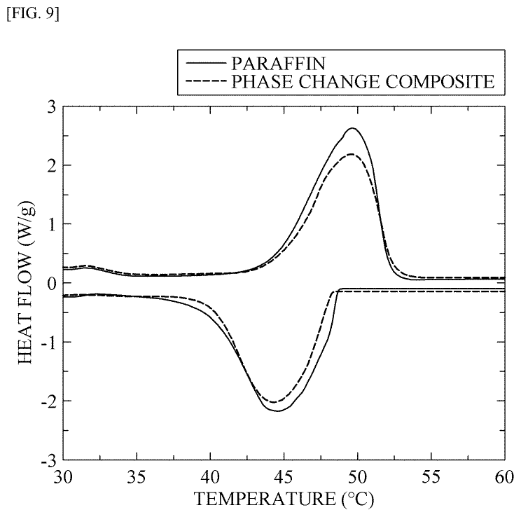

Differential scanning calorimetry (DSC) (DSC 4000, PERKIN ELMER) analysis on pure paraffin and the phase change composite manufactured in Manufacture Example 2 was performed, and the results are shown in FIG. 9. Latent heat was measured at a heating and cooling rate of 5 K/min under a constant nitrogen gas atmosphere of 50 ml/min.

The heat of fusion and specific heat of a heat spreader (phase change composite) were characterized by differential scanning calorimetry (DSC) (DSC 4000, PERKIN ELMER) analysis.

Referring to FIG. 9, the melting temperature and solidification temperature of the phase change composite manufactured in Manufacture Example 2 are ˜49° C. and ˜44° C., respectively, and pure paraffin has similar results. In a melting process, the amounts of latent heat of pure paraffin and the phase change composite manufactured in Manufacture Example 2 are 189.6±4.3 J/g and 135.7±1.5 J/g, respectively. This is a volume percentage level of about 88% (2% error range at 90% volume percentage level), and indicates that the amount of latent heat of the layer-by-layer phase change composite of Manufacture Example 2 is sufficient. In addition, the content of paraffin may be adjusted by controlling the shape of the aluminum mesh of the phase change material unit layer.

### Measurement Example. Measurement of Temperature Profiles of Thermal Diffusion Depending on Cooling Conditions

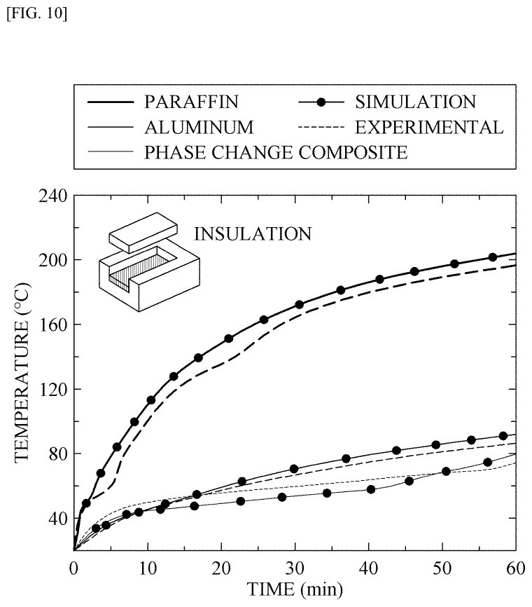

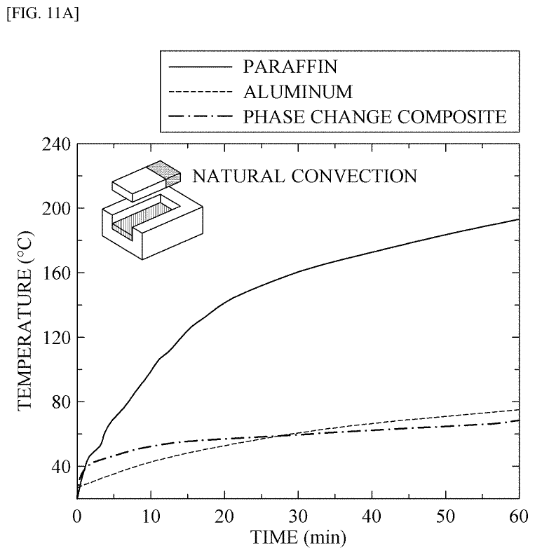

In the experimental apparatus of FIG. 6, a heating condition of 5 W was configured using a ceramic heater on the left side of the heat spreader, and all other parts were surrounded with a ceramic insulator to prevent heat leakage. Then, the hot-spot temperature (T₁) of the experimental apparatus of FIG. 6 was measured, and the results are shown in FIG. 10.

FIG. 10 shows the hot-spot temperature (T₁) values of the experimental apparatus of FIG. 6 calculated through the numerical simulation and actually measured values. The actually measured values (marked as Experimental) are 198±3.5° C. for pure paraffin, 84±1.1° C. for aluminum, and 77±2.5° C. for the phase change composite. Compared to calculated values (marked as Simulation) through numerical simulation, error rates are 3% for pure paraffin, 5% for aluminum, and 6% for the phase change composite.

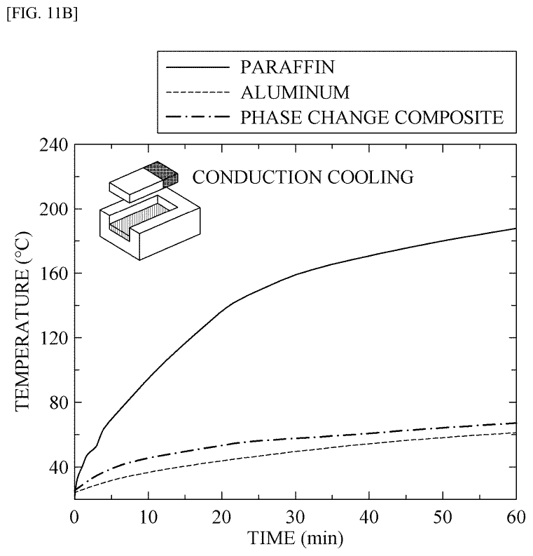

In the experimental apparatus of FIG. 6, a heating condition of 5 W was configured using a ceramic heater on the left side of the heat spreader, and cooling conditions (Cooling Section) by natural convection and conduction cooling were configured at the upper right part of the heat spreader. All other parts were surrounded with a ceramic insulator to prevent heat leakage. Then, the temperature of a heat generating portion was measured for 60 minutes to evaluate the performance of the heat spreader, and the results are shown in FIGS. 11A and 11B.

The temperature of the heat generating portion of each of pure paraffin (marked as Paraffin), aluminum block (marked as Aluminum), and the phase change composite manufactured in Manufacture Example 2 (marked as Phase Change Composite), which had the same volume, were measured for 60 minutes, and the results are shown in FIGS. 11A (natural convection) and 11B (conduction cooling) (a schematic diagram of an experimental apparatus for simply verifying cooling performance is shown in the upper left of FIG. 9).

Referring to FIGS. 11A and 11B, in the natural convection condition (FIG. 11A), the temperatures of pure paraffin, aluminum block, and the phase change composite manufactured in Manufacture Example 2 are 197±1.4° C., 75±0.4° C., and 70±0.5° C., respectively. In the conduction cooling condition (FIG. 11B), the temperatures of pure paraffin, aluminum block, and the phase change composite manufactured in Manufacture Example 2 are 187±1.8° C., 61±0.4° C., and 67±1.8° C., respectively. In the case of pure paraffin, due to too low thermal conductivity (0.2 W/k·m), heat stagnates at the heat generating portion of pure paraffin, causing overheating. Accordingly, from the beginning of heating, the temperature of the heat generating portion increases significantly, indicating that pure paraffin does not function as a heat spreader.

However, in the case of the layer-by-layer phase change material composite manufactured in Manufacture Example 2, since the thermal conductivity (57 W/k·m) in the horizontal direction was significantly increased, unlike the case of paraffin, no overheating of the heat generating portion was observed. At the beginning of heating, the temperature rise rate of the aluminum block is the lowest. This is because aluminum is cooled smoothly due to the highest thermal conductivity (230 W/m·K). However, from about 22 minutes, the temperature of the heat generating portion of the phase change composite manufactured in Manufacture Example 2 is lower than that of the aluminum block. The above results are due to the following causes: Heat is accumulated by endothermic reaction when the phase change of paraffin in the phase change composite manufactured in Manufacture Example 2 proceeds in the vicinity of 48 to 50° C., which is the phase change region of paraffin, and as a result, the heat of the heat generating portion is absorbed dramatically. Finally, even after 60 minutes, the temperatures of the heat generating portions of each of aluminum block and the phase change composite of Manufacture Example 2 are 75° C. and 70° C., respectively. Reduction in the temperature of the heat generating portion supports the excellent cooling performance of the phase change composite manufactured in Manufacture Example 2.

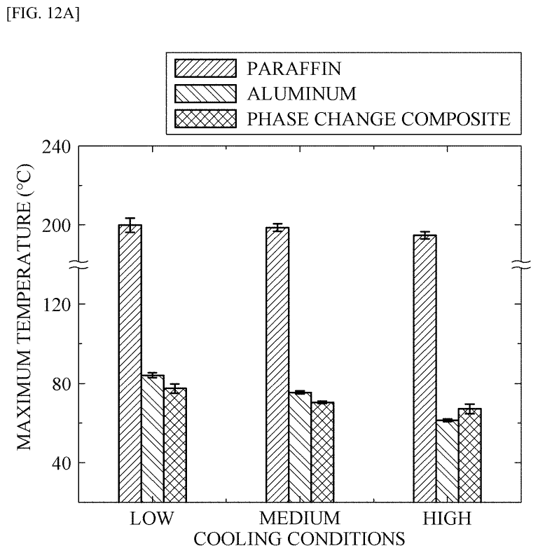

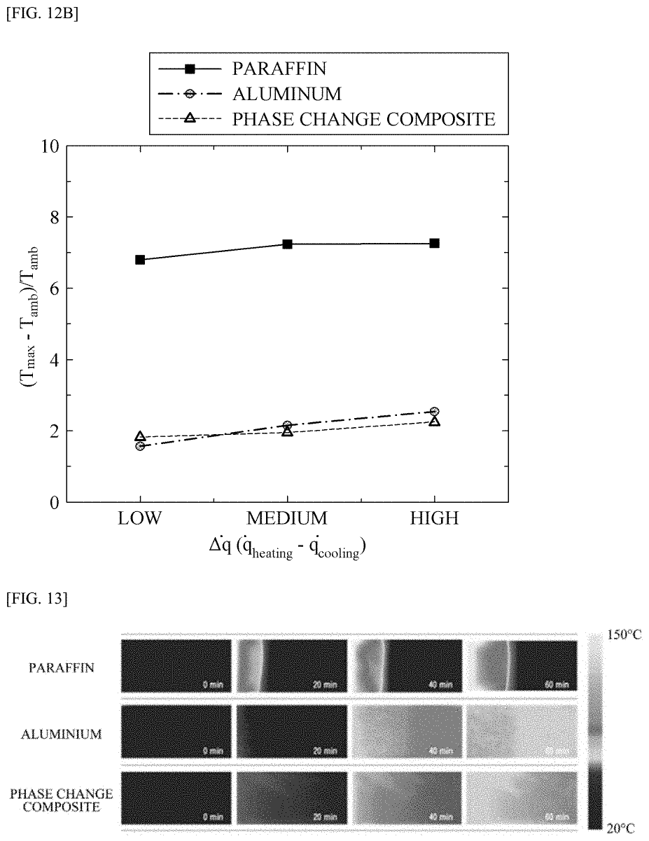

FIG. 12A shows the maximum temperatures (hot-spot temperatures) of pure paraffin (marked as Paraffin), the aluminum block (marked as Aluminum), and the phase change composite manufactured in Manufacture Example 2 (marked as Phase Change Composite) under low (insulator), medium (natural convection), and high (conduction cooling) conditions. FIG. 12B shows normalized temperature obtained by dividing the difference between maximum temperature and ambient temperature by the ambient temperature. Here, differences in heating and cooling fluxes are shown in low, medium, and high conditions.

Referring to FIGS. 12A and 12B, at lower cooling rates than heating rates, it may be more effective to use a phase change material due to a thermal capacitive effect on cooling.

FIG. 13 shows images, taken with a thermal imaging camera (T620, FLIR), showing the temperatures of pure paraffin (marked as Paraffin), the aluminum block (marked as Aluminum), and the phase change composite manufactured in Manufacture Example 2 (marked as Phase Change Composite) under exothermic conditions for 60 minutes.

Referring to FIG. 13, it can be seen that aluminum having the highest thermal conductivity has the best thermal diffusion performance. In addition, it can be confirmed that the phase change composite material manufactured in Manufacture Example 2 also has excellent thermal diffusion performance like aluminum.

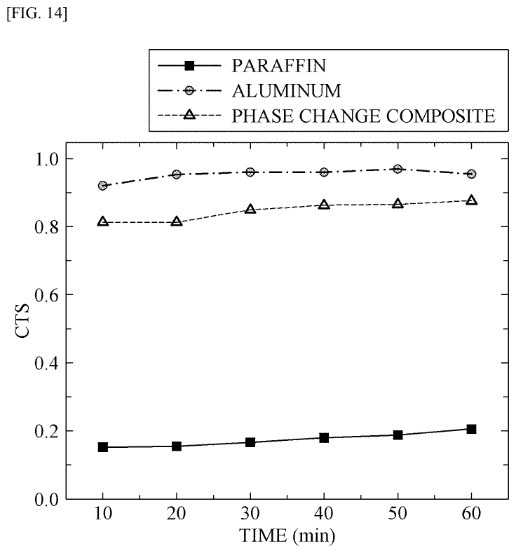

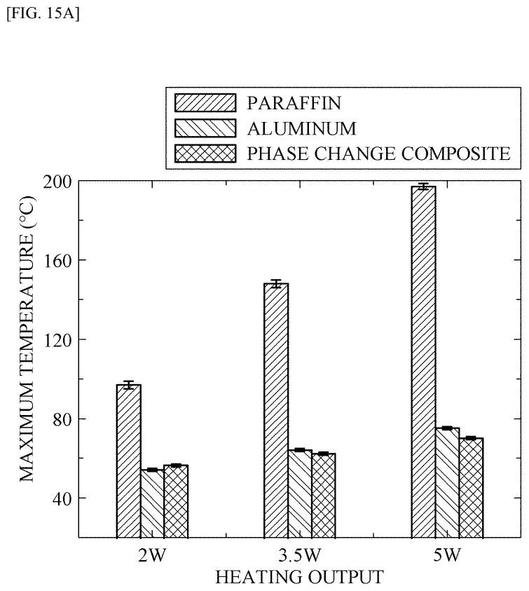

FIG. 14 shows the coefficients of thermal spreading (CTS) of pure paraffin (marked as Paraffin), the aluminum block (marked as Aluminum), and the phase change composite manufactured in Manufacture Example 2 (marked as Phase Change Composite) for the same time.

The coefficient of thermal spreading (CTS) of FIG. 14 is calculated by Equation 3 below.

$$CTS = \frac{{θ}_{average}}{{θ}_{max}} = ( {T}_{average} - {T}_{ambient} ) \text{/} ( {T}_{max} - {T}_{ambient} ) \qquad [ Equation 3 ]$$

The high coefficient of thermal spreading indicates that a heat spreader most affected by heat conduction has even heat distribution. The coefficient of thermal spreading (CTS) of the phase change composite manufactured in Manufacture Example 2 is slightly smaller than that of aluminum (0.096±0.033), and is significantly greater than that of pure paraffin.

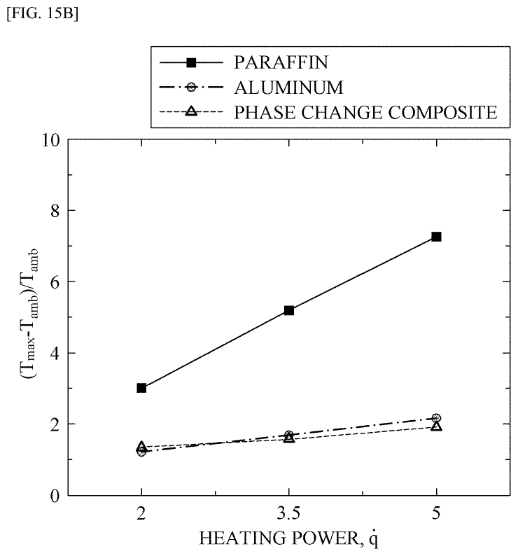

FIGS. 15A and 15B show the cooling performance of thermal identification under natural convection conditions according to heating power for pure paraffin (marked as Paraffin), the aluminum block (marked as Aluminum), and the phase change composite manufactured in Manufacture Example 2 (marked as Phase Change Composite), wherein FIG. 15A relates to maximum temperature (hot-spot temperature) and FIG. 15B relates to normalized temperature.

Referring to FIG. 15A, when pure paraffin (marked as Paraffin), the aluminum block (marked as Aluminum), and the phase change composite manufactured in Manufacture Example 2 (marked as Phase Change Composite) are heated with a heating power of 2/3.5/5 W for 60 minutes, maximum temperatures are 97±1.9/148±2.2/197±1.4° C. for pure paraffin, 54±0.5/64±0.5/75±0.4° C. for the aluminum block, and 56±0.9/62±0.6/70±0.5° C. for the phase change composite.

Referring to FIG. 15B, the maximum temperature of the phase change composite manufactured in Manufacture Example 2 is the lowest except for aluminum at a heat power of 2 W. This results suggests that, when lowering the maximum temperature of heat diffusion at a relatively high thermal budget due to a limited cooling resource (i.e., significant difference between heating rate and cooling rate), the phase change composite of Manufacture Example 2 may be more effective than aluminum.

In general, a heat spreader with a high CTS lowers the maximum temperature. Conventional heat spreaders rely on high thermal conductivity. The difference between CTS and the maximum temperature results from a cooling effect by a thermal capacitance. Accordingly, to examine cooling capacity in consideration of both thermal conductivity and capacitance, the approximated effective figure-of-merit (FOM_{eff}) of the tested sample was characterized, and FOM_{eff} was calculated by Equations 4 and 5 below.

FOM_{eff}(ΔT)=\sqrt{k·E_{eff}(ΔT)} [Equation 4]

[Equation 5]

In Equations 4 and 5, k represents thermal conductivity (W/m·K), E_{eff} represents effective volumetric thermal energy density (J/m3), C_{V} represents sensible volumetric heat capacity

E_{eff}(Φ,ΔT)=(C_{V,f}ΔT)Φ+(C_{V,pcm},ΔT+H_{V,pcm})(1−Φ)

(J/m³·K), T represents increased temperature (K), φ represents the volume percentage of a filler, H_{V} represents volumetric latent heat (J/m³), and subscripts f and pcm represent a filler and a phase change material, respectively.

The FOM_{eff} of pure paraffin (marked as Paraffin), the aluminum block (marked as Aluminum), and the phase change composite manufactured in Manufacture Example 2 (marked as Phase Change Composite) calculated at ΔT=1K are 0.58×10⁴ Jm⁻²(K·s)^{-1/2}, 2.36×10⁴ Jm⁻²(K·s)^{-1/2}, and 9.26×10⁴ Jm⁻²(K·s)^{-1/2}, respectively.

According to embodiments of the present disclosure, by repeatedly laminating thermal conductive layers and phase change material unit layers, thermal conductivity in the horizontal direction can be dramatically improved. In addition, due to a high volume percentage of a phase change material, a heat spreader with a large heat capacity can be provided.

In addition, due to the improved thermal conductivity of a phase change material and endothermic reaction by phase change, the cooling performance of a heat generating portion is excellent, and thermal diffusion performance is also excellent.

In addition, since the phase change composite of the present disclosure is manufactured using simple processes such as impregnation and compression, processability and productivity can be improved. Also, by adjusting the volume percentages of a metal mesh and a phase change material, the performance of a heat spreader can be improved.

Meanwhile, embodiments of the present disclosure disclosed in the present specification and drawings are only provided to aid in understanding of the present disclosure and the present disclosure is not limited to the embodiments. It will be apparent to those skilled in the art that various modifications can be made to the above-described exemplary embodiments of the present disclosure without departing from the spirit and scope of the invention.

What is claimed is:

1. A phase change composite, comprising a structure wherein phase change material unit layers and thermal conductive layers are sequentially laminated.

2. The phase change composite according to claim 1, wherein each of the phase change material unit layers comprises a metal mesh sheet in which a plurality of unit cells is formed; and a phase change material, wherein the unit cells are impregnated with the phase change material

3. The phase change composite according to claim 2, wherein each of the unit cells has a rectangular shape characterized in that a length thereof is longer than a width thereof based on a horizontal direction.

4. The phase change composite according to claim 2, wherein the phase change material is a salt hydrate, a molten salt, a fatty acid, a liquid metal (gallium, indium), a phase change material made up of molecular alloys (MCPAM), an organic phase change material, an inorganic phase change material, or a eutectic phase change material.

5. The phase change composite according to claim 2, wherein the phase change material is polyethylene glycol (PEG), paraffin, or erythritol.

6. The phase change composite according to claim 2, wherein the metal mesh sheet is formed of one or more selected from the group consisting of aluminum, copper, nickel, brass, iron, cadmium, gold, platinum, tungsten, zinc, zirconium, carbon steel, stainless steel, and galvanized steel.

7. The phase change composite according to claim 2, wherein thermal properties of the phase change composite change depending on changes in a volume percentage (vol %) of the metal mesh sheet and a volume percentage (vol %) of the phase change material.

8. The phase change composite according to claim 7, wherein the thermal properties comprise thermal conductivity and amount of heat absorption.

9. The phase change composite according to claim 1, wherein the thermal conductive layers are formed of one or more selected from the group consisting of graphite, graphene, carbon nanotube, fullerene, aluminum oxide, copper oxide, silver oxide, gold oxide, palladium oxide, platinum oxide, nickel oxide, and yttrium oxide.

10. A heat spreader, comprising the phase change composite of claim 1.

11. A method of manufacturing a phase change composite, comprising:
preparing a metal mesh sheet in which a plurality of unit cells is formed;
manufacturing phase change material unit layers by impregnating the unit cells with a phase change material;
manufacturing a laminated structure by sequentially and alternately laminating the phase change material unit layers and thermal conductive layers so that each of the thermal conductive layers is laminated on an upper portion of each of the phase change material unit layers; and
manufacturing the phase change composite by compressing the laminated structure.

12. The method according to claim 11, wherein the phase change material is a salt hydrate, a molten salt, a fatty acid, a liquid metal (gallium, indium), a phase change material made up of molecular alloys (MCPAM), an organic phase change material, an inorganic phase change material, or a eutectic phase change material.

13. The method according to claim 11, wherein the phase change material is polyethylene glycol (PEG), paraffin, or erythritol.

14. The method according to claim 11, wherein the metal mesh sheet is formed of one or more selected from the group consisting of aluminum, copper, nickel, brass, iron, cadmium, gold, platinum, tungsten, zinc, zirconium, carbon steel, stainless steel, and galvanized steel.

15. The method according to claim 11, wherein the thermal conductive layers are formed of one or more selected from the group consisting of graphite, graphene, carbon nanotube, fullerene, aluminum oxide, copper oxide, silver oxide, gold oxide, palladium oxide, platinum oxide, nickel oxide, and yttrium oxide.
